(19) United States
(12) Patent Application Publication
(10) Pub. No.: US 2011/0254633 A1
(43) Pub. Date: Oct. 20, 2011

(54) METHOD AND APPARATUS FOR ALLEVIATING CHARGE LEAKAGE OF VCO FOR PHASE LOCK LOOP

(75) Inventors: Chia-Liang LIN, Fremont, CA (US); Chao-Cheng LEE, Hsinchu City (TW)

(73) Assignee: REALTEK SEMICONDUCTOR CORP., Hsinchu (TW)

(21) Appl. No.: 12/759,700

(22) Filed: Apr. 14, 2010

(51) Int. Cl. H03L 7/06

(52) U.S. Cl. 331/17

(57) ABSTRACT

Methods and apparatuses for alleviating charge leakage of VCO for phase lock loop are disclosed. The method comprises: receiving an input signal; generating an error signal representing a timing difference between the input signal and an output signal; filtering the error signal into a control signal; buffering the control signal into a buffered control signal; and generating the output signal in accordance with the buffered control signal. Buffering the control signal comprising using a high input resistance and low output resistance buffer circuit.

### FIELD OF TECHNOLOGY

This disclosure relates to phase lock loop.

### BACKGROUND

Phase lock loop (PLL) is useful for many applications. As depicted in FIG. 1, a typical PLL 100 comprises: a phase detector 110 for generating an error signal ERR representing a timing difference between an input signal IN and an output signal OUT; a loop filter 130 for filtering the error signal ERR into a control voltage VC; and a voltage-controlled oscillator (VCO) 120 for generating the output signal under control of the control voltage VC. A timing of the output signal OUT is thus adjusted in a closed-loop manner to track a timing of the input signal IN. In a typical embodiment, the error signal ERR is a current mode signal and the loop filter 130 comprises a capacitor to hold the control voltage VC. When using deep submicron CMOS (complementary metal-oxide semiconductor) devices to implement a PLL, however, the VCO may be prone to charge leakage at the input node coupled to the control voltage VC. The control voltage VC held at the capacitor of the loop filter 130, therefore, is subject to decline due to the charge leakage. Such decline can be corrected by PLL in a closed-loop manner such that an average value of the control voltage VC is still maintained as long as the PLL adapts faster than a rate of the decline, the control voltage. However, the control voltage is noisy and accordingly the output is noisy due to the charge leakage.

What is needed is a method and apparatus for alleviating charge leakage of VCO for PLL.

### BRIEF SUMMARY OF THIS INVENTION

In an embodiment, an apparatus is disclosed, the apparatus comprising: a phase detector for outputting an error signal in accordance with a timing difference between an input signal and an output signal; a loop filter for filtering the error signal into a first voltage signal; a voltage buffer for buffering the first voltage signal into a second voltage signal; and a voltage controlled oscillator (VCO) for outputting the output signal under control of the second voltage signal. An input resistance of the voltage buffer is sufficiently high; an output resistance of the voltage buffer is sufficiently low; and a bandwidth of the voltage buffer is sufficiently high; therefore, the second voltage signal effectively tracks the first voltage signal.

In an embodiment, a method is disclosed, the method comprising: receiving an input signal; generating an error signal representing a timing difference between the input signal and an output signal; filtering the error signal into a control signal; buffering the control signal into a buffered control signal; and generating the output signal in accordance with the buffered control signal. Buffering the control signal comprising using a high input resistance and low output resistance buffer circuit.

### BRIEF DESCRIPTION OF THE DRAWINGS

FIG. 1 shows a functional block diagram of a phase lock loop.

FIG. 2 shows a functional block diagram of a phase lock loop in accordance with the present invention.

FIG. 3 shows an embodiment of a voltage buffer in accordance with the present invention.

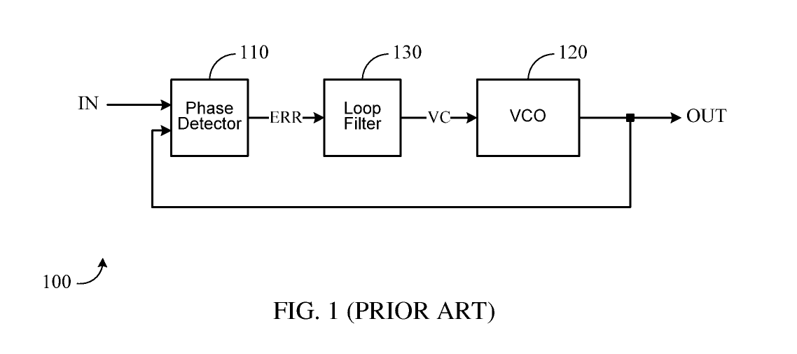

### DETAILED DESCRIPTION

The following detailed description refers to the accompanying drawings which show, by way of illustration, various embodiments in which the invention may be practiced. These embodiments are described in sufficient detail to enable those skilled in the art to practice these and other embodiments. The various embodiments are not necessarily mutually exclusive, as some embodiments can be combined with one or more other embodiments to form new embodiments. The following detailed description is, therefore, not to be taken in a limiting sense.

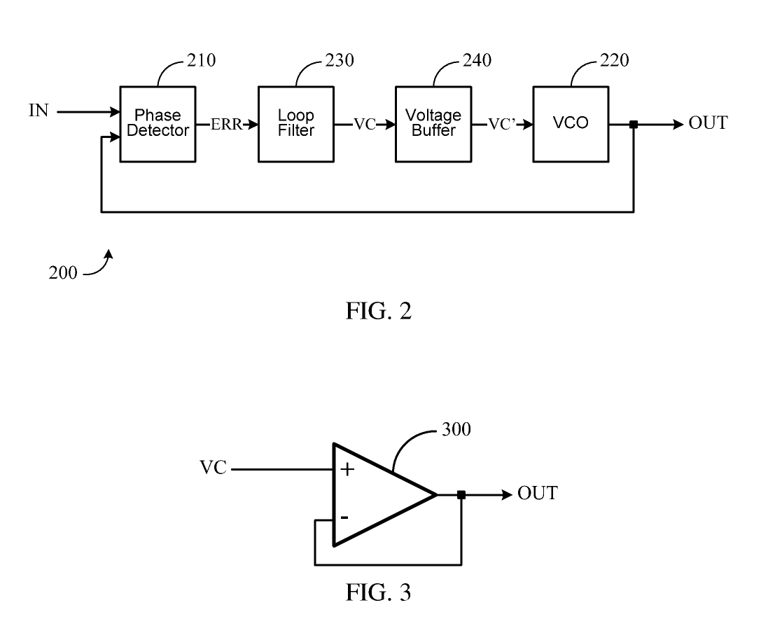

FIG. 2 shows a functional block diagram of a PLL 200 in accordance with the present invention. PLL 200 comprises: a phase detector 210 for generating an error signal ERR representing a timing difference between an input signal IN and an output signal OUT; a loop filter 230 for filtering the error signal ERR into a control voltage VC; a voltage buffer 240 for receiving the control voltage VC and outputting a buffered control voltage VC′, and a voltage-controlled oscillator (VCO) 220 for generating the output signal under control of the buffered control voltage VC′.

In an embodiment, an input resistance of the voltage buffer 240 is substantially large such that there is substantially zero charge leakage to the control voltage VC resulting from interfacing to the voltage buffer 240. An output resistance of the voltage buffer 240 is substantially small such that the buffered controlled voltage VC′ is substantially unaffected by the charge leakage at of the VCO 220. The problem of the charge leakage of the VCO 220 is thus alleviated. To avoid affecting a stability of PLL 200, the voltage buffer 240 should have a bandwidth that is substantially higher than a bandwidth of the control voltage VC such that the buffered control voltage VC′ effectively tracks the control voltage VC.

In an embodiment, the phase detector 210 is a binary phase detector (BPD) generating a phase signal representing a result of a timing comparison between the input signal and the output signal. The phase signal comprises two logical signals. In an alternative embodiment, the phase detector 210 is a phase-frequency detector (PFD) generating a phase signal representing a result of a timing comparison between the input signal and the output signal. The phase signal comprises two logical signals. Both BPD and PFD and the resultant phase signal comprising two logical signals are well known in prior art and thus not described in detail here.

In an embodiment, the error signal ERR is a current-mode signal generated by a charge pump circuit and the loop filer 230 comprises a capacitor to convert the current-mode signal into the control voltage VC. The charge pump circuit converts a phase signal (representing a result of a phase detection, usually comprising two logical signals) into the current-mode signal ERR, and the subsequent loop filter circuit comprising the capacitor converts the current-mode signal ERR in the voltage signal VC. Embodiments of charge pump circuit and loop filter are well known in prior art and thus not described in detailed here.

In an embodiment depicted in FIG. 3, the voltage buffer 240 of FIG. 2 comprises an operational amplifier 300 configured in a non-inverting feedback topology, wherein a positive input node is coupled to the controlled voltage VC and a negative input node is coupled to the buffered control voltage VC′. Operational amplifier 300 has a substantially high input resistance, a substantially low output resistance, and a substantially high bandwidth such that the buffered control voltage VC′ effectively tracks the control voltage VC.

Although specific embodiments have been illustrated and described herein, it will be appreciated by those of ordinary skill in the art that any arrangement that is calculated to achieve the same purpose may be substituted for the specific embodiments shown. This application is intended to cover adaptations and variations of the embodiments discussed herein. Various embodiments use permutations and/or combinations of embodiments described herein. It is to be understood that the above description is intended to be illustrative, and not restrictive, and that the phraseology or terminology employed herein is for the purpose of description.

What is claimed is:

1. An apparatus comprising:
a phase detector for outputting an error signal in accordance with a timing difference between an input signal and an output signal;
a loop filter for filtering the error signal into a first voltage signal;
a voltage buffer for buffering the first voltage signal into a second voltage signal; and
a voltage controlled oscillator (VCO) for outputting the output signal under control of the second voltage signal.

2. The apparatus of claim 1, wherein: an input resistance of the voltage buffer is sufficiently high such that there is substantially zero charge leakage to the control voltage.

3. The apparatus of claim 1, wherein an output resistance of the voltage buffer is sufficiently low such that the buffered controlled voltage is substantially unaffected by the charge leakage at of the VCO.

4. The apparatus of claim 1, wherein a bandwidth of the voltage buffer is sufficiently high, such that the second voltage signal effectively tracks the first voltage signal.

5. The apparatus of claim 1, wherein the voltage buffer comprises an operational amplifier configured in a non-inverting feedback topology.

6. The apparatus of claim 5, wherein the phase detector comprises one of the following: binary phase detector, phase-frequency detector, for generating a phase signal.

7. The apparatus of claim 6, wherein the phase detector further comprises a charge pump circuit to convert the phase signal into a current-mode signal.

8. The apparatus of claim 8, wherein the loop filter comprises a capacitor for holding the first voltage signal.

9. The apparatus of claim 1, wherein the apparatus is implemented by using a deep submicron CMOS (complementary metal-oxide semiconductor) device.

10. A method comprising:
receiving an input signal;
generating an error signal representing a timing difference between the input signal and an output signal;
filtering the error signal into a control signal;
using a buffer circuit to buffer the control signal into a buffered control signal; and
generating the output signal in accordance with the buffered control signal.

11. The method of claim 10, wherein the buffer circuit is a high-bandwidth circuit with a bandwidth substantially higher than a bandwidth of the control signal.

12. The method of claim 10, wherein buffering the control signal comprises using a high input resistance low output resistance buffer circuit.

13. The method of claim 10, wherein the error signal is a current-mode signal generated by a charge pump.

14. The method of claim 10, wherein the control signal is a voltage signal.

15. The method of claim 14, wherein filtering the error signal comprises using a filter circuit comprising a capacitor for holding the voltage signal.

16. A method comprising:
receiving an input signal;
generating an error signal representing a timing difference between the input signal and an output signal;
filtering the error signal into a first control signal;
tracking the first control signal to generate a second control signal; and
generating the output signal in accordance with the second control signal.

17. The method of claim 16, wherein the step of tracking the first control signal comprises using a buffer circuit to buffer the first control signal.

18. The method of claim 17, wherein the buffer circuit is a high-bandwidth circuit with a bandwidth substantially higher than a bandwidth of the first control signal.

19. The method of claim 17, wherein the buffer circuit is a high input resistance low output resistance buffer circuit.
